(19) United States
(12) Patent Application Publication
(10) Pub. No.: US 2023/0020837 A1
(43) Pub. Date: Jan. 19, 2023

(54) MAGNETIC SENSOR

(71) Applicant: SHOWA DENKO K.K., Tokyo (JP)

(72) Inventors: Daizo ENDO, Ichihara-shi, Chiba (JP); Tatsunori SHINO, Ichihara-shi, Chiba (JP)

(73) Assignee: SHOWA DENKO K.K., Tokyo (JP)

(21) Appl. No.: 17/785,504

(22) PCT Filed: Nov. 17, 2020
(86) PCT No.: PCT/JP2020/042699

§ 371 Date: Jun. 15, 2022

(30) Foreign Application Priority Data
Dec. 25, 2019 (JP) 2019-235075

(51) Int. Cl. G01R 33/06

(52) U.S. Cl. CPC G01R 33/063

(57) ABSTRACT

A magnetic sensor includes: a sensitive layer made of a soft magnetic material with uniaxial magnetic anisotropy, the sensitive layer being configured to sense a magnetic field by a magnetic impedance effect; and a magnet layer made of a magnetized hard magnetic material and disposed to face the sensitive layer. The magnet layer is configured to apply a DC magnetic bias Hb in a direction intersecting a direction of the uniaxial magnetic anisotropy in the sensitive layer, the DC magnetic bias Hb having a greater value than an anisotropic magnetic field Hk of the sensitive layer.

### TECHNICAL FIELD

The present invention relates to a magnetic sensor.

### BACKGROUND ART

A previous publication in the art discloses a magnetic impedance effect element including: a thin-film magnet composed of a hard magnetic material film formed on a non-magnetic substrate; an insulating layer covering the thin-film magnet; and a magneto-sensitive portion formed on the insulating layer and composed of one or more rectangular soft magnetic material films with uniaxial anisotropy (see Patent Document 1).

Another previous publication in the art discloses a magnetic sensor including: a thin-film magnet composed of a hard magnetic material layer with magnetic anisotropy in an in-plane direction; a sensitive portion including a sensitive element configured to sense a magnetic field by a magnetic impedance effect, the sensitive element being composed of a soft magnetic material layer laminated on the hard magnetic material layer, the sensitive element having a longitudinal direction and a transverse direction and having uniaxial magnetic anisotropy in a direction intersecting the longitudinal direction, the longitudinal direction being oriented in a direction of a magnetic field generated by the thin-film magnet, where a magnetic bias Hb, which is a magnetic field applied to the sensitive element (soft magnetic material layer) using the thin-film magnet, is selected from a range smaller than an anisotropic magnetic field Hk of the soft magnetic material layer (see Patent Document 2).

### CITATION LIST

### Patent Literature

Patent Document 1: Japanese Patent Application Laid-Open Publication No. 2008-249406

Patent Document 2: Japanese Patent Application Laid-Open Publication No. 2019-100847

### SUMMARY OF INVENTION

### Technical Problem

However, if the magnetic bias applied to the sensitive element (soft magnetic material layer) is selected from the range smaller than the anisotropic magnetic field Hk of the soft magnetic material layer, an SN ratio, which represents a ratio between signal and noise at the output of the magnetic sensor, may decrease.

It is an object of the present invention to reduce a decrease in the SN ratio at the output of the magnetic sensor using the magnetic impedance effect.

### Solution to Problem

A magnetic sensor according to an aspect of the present invention includes: a sensitive layer made of a soft magnetic material with uniaxial magnetic anisotropy, the sensitive layer being configured to sense a magnetic field by a magnetic impedance effect; and a magnet layer made of a magnetized hard magnetic material and disposed to face the sensitive layer, the magnet layer being configured to apply a DC magnetic bias in a direction intersecting a direction of the uniaxial magnetic anisotropy in the sensitive layer, the DC magnetic bias having a greater value than an anisotropic magnetic field of the sensitive layer.

The magnet layer may be configured to apply, as the DC magnetic bias, a magnetic field with a largest slope in a magnetic field-impedance curve within a range of values greater than the anisotropic magnetic field of the sensitive layer, the magnetic field-impedance curve associating magnetic fields applied to the sensitive layer with changes in impedance of the sensitive layer.

The magnetic sensor may further include a guiding layer configured to guide magnetic lines of force passing through the magnet layer to the sensitive layer.

A magnetic sensor according to another aspect of the present invention includes: a sensitive element made of a soft magnetic material, the sensitive element having a longitudinal direction and a transverse direction, the sensitive element having uniaxial magnetic anisotropy in a direction intersecting the longitudinal direction, the sensitive element being configured to sense a magnetic field by a magnetic impedance effect; and an applicator configured to apply a DC magnetic bias in the longitudinal direction of the sensitive element, the DC magnetic bias corresponding to a saturation magnetic field of the sensitive element.

### Advantageous Effects of Invention

The present invention can reduce a decrease in the SN ratio at the output of the magnetic sensor using the magnetic impedance effect.

### BRIEF DESCRIPTION OF DRAWINGS

FIGS. 1A and 1B illustrate an example magnetic sensor according to an embodiment.

FIG. 2A illustrates relationship between an external magnetic field applied in the longitudinal direction of a sensitive element of the magnetic sensor and an impedance generated in the sensitive element. FIG. 2B illustrates relationship between the external magnetic field applied in the longitudinal direction of the sensitive element of the magnetic sensor and changes in impedance of the sensitive element relative to changes in the external magnetic field.

FIGS. 3A and 3B illustrate the magnitude of the magnetic bias applied to the sensitive element of the magnetic sensor of the present embodiment.

FIGS. 4A to 4D illustrate relationship between the strength of the magnetic field applied to the sensitive element of the magnetic sensor of the present embodiment and changes in magnetic domains in the sensitive element.

FIG. 5 illustrates relationship between the strength of the magnetic field applied to the sensitive element of the magnetic sensor of the present embodiment and the magnetization strength in the sensitive element.

FIG. 6 is a photograph capturing the state of magnetic domains when a DC magnetic bias with a magnitude A (+0.5 Oe) was applied to the sensitive element of the magnetic sensor.

FIG. 7 is a photograph capturing the state of magnetic domains when a DC magnetic bias with a magnitude B (+8.3 Oe) was applied to the sensitive element of the magnetic sensor.

FIG. 8 is a photograph capturing the state of magnetic domains when a DC magnetic bias with a magnitude C (+14.3 Oe) was applied to the sensitive element of the magnetic sensor.

FIGS. 9A to 9C illustrate relationship between signals and noise output from the magnetic sensor and an SN ratio.

### DESCRIPTION OF EMBODIMENTS

An exemplary embodiment of the present invention will be described below with reference to the attached drawings. In the drawings as referred to in the below description, dimensions of each component, including size and thickness, may differ from actual ones.

### Configuration of Magnetic Sensor 1

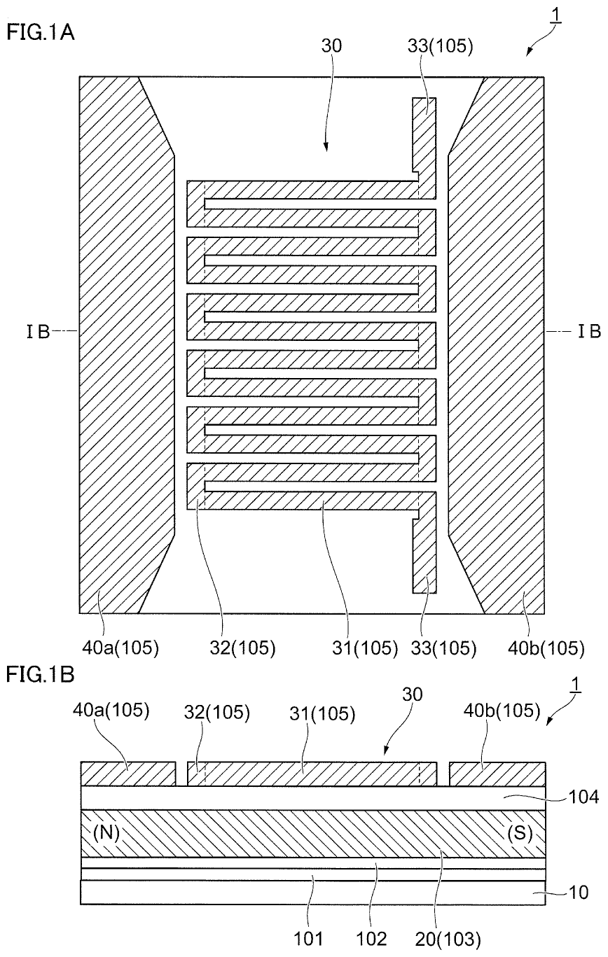

FIGS. 1A and 1B illustrate an example magnetic sensor 1 according to an embodiment; FIG. 1A is a plan view, and FIG. 1B is a cross-sectional view along the line IB-IB in FIG. 1A.

As shown in FIG. 1B, the magnetic sensor 1 according to the present embodiment includes a thin-film magnet 20 disposed on a non-magnetic substrate 10 and made of a hard magnetic material (hard magnetic material layer 103), and a sensitive portion 30 laminated to face the thin-film magnet 20 and made of a soft magnetic material (soft magnetic material layer 105) to sense a magnetic field. A cross-sectional structure of the magnetic sensor 1 will be detailed in subsequent paragraphs.

The hard magnetic material refers to a so-called high coercivity material that, once being magnetized by an external magnetic field, keeps its magnetized state even after removal of the external magnetic field. The soft magnetic material refers to a so-called low coercivity material that is easily magnetizable by an external magnetic field but quickly returns to a non-magnetized or low magnetized state upon removal of the external magnetic field.

Herein, elements constituting the magnetic sensor 1 (e.g., thin-film magnet 20) is denoted by two-digit reference numerals, and layers processed into these elements (e.g., hard magnetic material layer 103) are denoted by reference numerals in the 100s. And the reference numeral for each layer processed into a corresponding element is placed in parentheses following the reference numeral for the corresponding element. For example, the thin-film magnet 20 is denoted as “the thin-film magnet 20 (hard magnetic material layer 103)”. In the figures, the reference numerals are presented as “20(103)”. This holds for other elements.

Referring to FIG. 1A, a planar structure of the magnetic sensor 1 is described. By way of example, the magnetic sensor 1 has a square planar shape. Here, a description is given of the sensitive portion 30 and yokes 40 formed in the uppermost part of the magnetic sensor 1. The sensitive portion 30 includes: plural sensitive elements 31 each being of a strip-like planar shape having longitudinal and transverse directions; connecting portions 32 connecting respective adjacent sensitive elements 31 in series in a serpentine pattern; and terminal portions 33 connected with electric wires. In the shown example, twelve sensitive elements 31 are arranged such that their longitudinal directions are parallel to each other. The sensitive elements 31 are magnetic impedance effect elements.

Each sensitive element 31 as an example of the sensitive layer has, for example, a longitudinal length of from 1 mm to 2 mm, a transversal width of from 50 μm to 150 μm, a thickness (thickness of the soft magnetic material layer 105) of from 0.5 μm to 5 μm. A distance between adjacent sensitive elements 31 is from 50 μm to 150 μm. Preferably, the transversal width of each sensitive element 31 is smaller than the distance between adjacent sensitive elements 31.

Each connecting portion 32 is disposed between ends of respective adjacent sensitive elements 31 to connect the respective adjacent sensitive elements 31 in series in a serpentine pattern. As the magnetic sensor 1 shown in FIG. 1A includes twelve sensitive elements 31 arranged in parallel, there are eleven connecting portions 32. The number of connecting portions 32 varies depending on the number of sensitive elements 31. For example, when there are four sensitive elements 31, three connecting portions 32 will be provided. When there is only one sensitive element 31, no connecting portion 32 will be provided. The width of the connecting portion 32 may be set according to factors such as the size of pulsed voltage applied to the sensitive portion 30. For example, the width of the connecting portion 32 may be same as that of the sensitive element 31.

The terminal portions 33 are disposed at (two) respective ends of the sensitive elements 31 that are not connected with any connecting portion 32. The terminal portion 33 may have a size that allows for connection of the electric wires. Since the sensitive portion 30 of the present embodiment includes twelve sensitive elements 31, the two terminal portions 33 are arranged on the right side in FIG. 1A. When the sensitive elements 31 are odd in number, the two terminal portions 33 may be arranged respectively on the right and left sides.

The sensitive elements 31, the connecting portions 32, and the terminal portions 33 of the sensitive portion 30 are integrally formed of a single soft magnetic material layer 105. As the soft magnetic material layer 105 is conductive, electric currents flow from one terminal portion 33 to the other terminal portion 33.

Note that the size (length, width, area, thickness, etc.) of the sensitive element 31 and other components of the sensitive portion 30, the number of sensitive elements 31, the distance between adjacent sensitive elements 31, and other parameters are set according to factors such as the magnitude (amplitude) of the applied pulsed voltage, the magnitude of the magnetic field to be sensed by the magnetic sensor 1, and the kind of soft magnetic material used for the sensitive portion 30.

The magnetic sensor 1 further includes the yokes 40 facing longitudinal ends of the sensitive elements 31. In this example, the magnetic sensor 1 includes two yokes 40a, 40b facing respective longitudinal ends of each sensitive element 31. Hereinafter, the yokes 40a, 40b may be simply referred to as the yokes 40 unless the distinction is necessary. The yokes 40, which are an example of the guiding layer, induce (guide) magnetic lines of force to the longitudinal ends of the sensitive elements 31. Hence, the yokes 40 are made of a soft magnetic material (soft magnetic material layer 105) that easily transmits the magnetic lines of force. That is, the sensitive portion 30 and the yokes 40 are composed of the single soft magnetic material layer 105. Note that the yokes 40 may be eliminated when the magnetic lines of force can sufficiently pass through the sensitive elements 31 in the longitudinal direction thereof.

From the above, the magnetic sensor 1 is several millimeters square in planar shape. Note that the size of the magnetic sensor 1 may be any other value.

Referring now to FIG. 1B, a cross-sectional structure of the magnetic sensor 1 is described. The magnetic sensor 1 is composed of the non-magnetic substrate 10 and a lamination of an adhesive layer 101, a control layer 102, the hard magnetic material layer 103 (the thin-film magnet 20), a dielectric layer 104, and the soft magnetic material layer 105 (the sensitive portion 30 and the yokes 40), which are laminated in this order on the substrate 10.

The substrate 10 is made of a non-magnetic material. Examples of the substrate 10 include an oxide substrate such as glass and sapphire, a semiconductor substrate such as silicon, and a metal substrate such as aluminum, stainless steel, and a metal plated with nickel phosphorus.

The adhesive layer 101 increases adhesiveness of the control layer 102 to the substrate 10. The adhesive layer 101 may be made of an alloy containing Cr or Ni. Examples of the alloy containing Cr or Ni include CrTi, CrTa, and NiTa. The adhesive layer 101 is from 5 nm to 50 nm thick, for example. Note that the adhesive layer 101 may be eliminated when the control layer 102 has sufficient adhesiveness to the substrate 10. Also note that the composition ratio of the alloy containing Cr or Ni will not be described herein. This holds for other alloys given below.

The control layer 102 controls the magnetic anisotropy of the thin-film magnet 20, which is formed of the hard magnetic material layer 103, such that the magnetic anisotropy easily develops in an in-plane direction of the film. The control layer 102 may be made of Cr, Mo, W, or an alloy containing at least one of these metals (hereinafter referred to as an alloy containing Cr or the like constituting the control layer 102). Examples of the alloy containing Cr or the like constituting the control layer 102 include CrTi, CrMo, CrV, and CrW. The control layer 102 is from 10 nm to 300 nm thick, for example.

The hard magnetic material layer 103 constituting the thin-film magnet 20 as an example of the magnet layer and the applicator may be a Co-based alloy containing either Cr or Pt or both (hereinafter referred to as a Co alloy constituting the thin-film magnet 20). Examples of the Co alloy constituting the thin-film magnet 20 include CoCrPt, CoCrTa, CoNiCr, and CoCrPtB. The Co alloy constituting the thin-film magnet 20 may also contain Fe. The hard magnetic material layer 103 is from 1 μm to 3 μm thick, for example.

The alloy containing Cr or the like constituting the control layer 102 has a body-centered cubic (bcc) structure. Thus, the hard magnetic material (hard magnetic material layer 103) constituting the thin-film magnet 20 preferably has a hexagonal close-packed (hcp) structure, which facilitates crystal growth on the control layer 102 composed of the alloy containing Cr or the like having the bcc structure. Such crystal growth, on the bcc structure, of the hard magnetic material layer 103 having the hcp structure can easily cause a c-axis of the hcp structure to be oriented in the in-plane direction. Consequently, the thin-film magnet 20, which is composed of the hard magnetic material layer 103, can easily have the magnetic anisotropy in the in-plane direction. Note that the hard magnetic material layer 103 has a polycrystalline structure composed of a group of differently oriented crystallites, and each crystallite has magnetic anisotropy in the in-plane direction. This magnetic anisotropy is derived from magneto-crystalline anisotropy.

To facilitate the crystal growth of the alloy containing Cr or the like constituting the control layer 102 and the Co alloy constituting the thin-film magnet 20, the substrate 10 may be heated to 100° C. to 600° C. This heating facilitates the crystal growth of the alloy containing Cr or the like constituting the control layer 102 and thus facilitates the crystal orientation of the hard magnetic material layer 103 so as to yield an easy axis of magnetization in the plane of the hard magnetic material layer 103 having the hcp structure. In other words, the heating facilitates impartation of the in-plane magnetic anisotropy to the hard magnetic material layer 103.

The dielectric layer 104 is made of a non-magnetic dielectric and provides electrical insulation between the thin-film magnet 20 and the sensitive portion 30. Examples of the dielectric constituting the dielectric layer 104 include oxides such as SiO₂, Al₂O₃ and TiO₂ and nitrides such as Si₃N₄ and AlN. The dielectric layer 104 is from 0.1 μm to 30 μm thick, for example.

Each sensitive element 31 of the sensitive portion 30 is provided with uniaxial magnetic anisotropy in a direction intersecting the longitudinal direction, e.g., in the transverse direction perpendicular to the longitudinal direction. Note that the direction intersecting the longitudinal direction may be a direction angled at 45 degrees or more with respect to the longitudinal direction.

The soft magnetic material layer 105 constituting the sensitive element 31 may be made of a Co-based amorphous alloy doped with a high melting point metal such as Nb, Ta, or W (hereinafter referred to as a Co alloy constituting the sensitive element 31). Examples of the Co alloy constituting the sensitive element 31 include CoNbZr, CoFeTa, and CoWZr. Each soft magnetic material layer 105 constituting the sensitive element 31 is from 0.2 μm to 2 μm thick, for example.

The adhesive layer 101, the control layer 102, the hard magnetic material layer 103, and the dielectric layer 104 are processed to have a square planar shape (see FIG. 1). Two opposing exposed sides of the thin-film magnet 20 are the north pole ((N) in FIG. 1B) and the south pole ((S) in FIG. 1B). A line connecting the north and south poles of the thin-film magnet 20 is oriented in the longitudinal direction of the sensitive element 31 of the sensitive portion 30. The phrase “oriented in the longitudinal direction” means that the line connecting the north and south poles is angled at 45 degrees or less with respect to the longitudinal direction. The smaller the angle between the line connecting the north and south poles and the longitudinal direction, the better.

In the magnetic sensor 1, magnetic lines of force emanating from the north pole of the thin-film magnet 20 once exit from the magnetic sensor 1. Then, some of the magnetic lines of force pass through the sensitive elements 31 via the yoke 40a and again exit from the magnetic sensor 1 via the yoke 40b. Thus, the magnetic lines of force having passed through the sensitive elements 31 return to the south pole of the thin-film magnet 20 together with other magnetic lines of force that have not passed through the sensitive elements 31. In other words, the thin-film magnet 20 applies a magnetic field in the longitudinal direction of the sensitive elements 31.

Note that the north and south poles of the thin-film magnet 20 are hereinafter collectively referred to as “both magnetic poles”, and each of the north and south poles is hereinafter referred to as a “magnetic pole” unless the distinction is necessary.

As shown in FIG. 1A, when viewed from the top side of the substrate 10, each of the yokes 40 (yokes 40a, 40b) has a shape that narrows as it approaches the sensitive portion 30. This shape is intended to concentrate the magnetic field (gather the magnetic lines of force) at the sensitive portion 30. In other words, this shape helps further improve the sensitivity by enhancing the magnetic field at the sensitive portion 30. Note that the yokes 40 (yokes 40a, 40b) are not necessarily narrowed at the portions thereof facing the sensitive portion 30.

A distance between each of the yokes 40 (yokes 40a, 40b) and the sensitive portion 30 may be from 1 μm to 100 μm, for example.

### Method for Manufacturing the Magnetic Sensor 1

An exemplary method for manufacturing the magnetic sensor 1 is now described.

As described above, the substrate 10 is a substrate made of a non-magnetic material, examples of which include an oxide substrate such as glass and sapphire, a semiconductor substrate such as silicon, and a metal substrate such as aluminum, stainless steel, and a metal plated with nickel phosphorus. The substrate 10 may be formed with linear grooves or linear protrusions and recesses with a curvature radius Ra of e.g., from 0.1 nm to 100 nm by means of a polishing machine or the like. The direction of these linear grooves or linear protrusions and recesses may be aligned with the direction connecting the north and south poles of the thin-film magnet 20 composed of the hard magnetic material layer 103. This facilitates the crystal growth in the hard magnetic material layer 103 in the direction of the grooves. This in turn helps to cause the easy axis of magnetization of the thin-film magnet 20 composed of the hard magnetic material layer 103 to be oriented in the direction of the grooves (direction connecting the north and south poles of the thin-film magnet 20). In other words, the thin-film magnet 20 can be magnetized more easily.

By way of example, the substrate 10 discussed herein is assumed to be glass with a diameter of about 95 mm and a thickness of about 0.5 mm. In the case where the magnetic sensor 1 is several millimeters square in planar shape, multiple magnetic sensers 1 are manufactured in a batch on the substrate 10 and then divided (cut) into individual magnetic sensers 1.

After cleaning of the substrate 10, the adhesive layer 101, the control layer 102, the hard magnetic material layer 103, and the dielectric layer 104 are deposited (stacked) in this order on one side (hereinafter referred to as a “top side”) of the substrate 10 to thereby form a laminate thereon.

First, the adhesive layer 101 of the alloy containing Cr or Ni, the control layer 102 of the alloy containing Cr or the like, and the hard magnetic material layer 103 of the Co alloy constituting the thin-film magnet 20 are successively deposited (stacked) in this order. This deposition may be done by a sputtering method or the like. The substrate 10 is moved to successively face multiple targets made of respective materials, whereby the adhesive layer 101, the control layer 102, and the hard magnetic material layer 103 are laminated in this order on the substrate 10. As described above, the substrate 10 may be heated to e.g., 100° C. to 600° C. during formation of the control layer 102 and the hard magnetic material layer 103 to facilitate the crystal growth.

The substrate 10 may or may not be heated during the deposition of the adhesive layer 101. The substrate 10 may be heated prior to the deposition of the adhesive layer 101 to remove moisture or the like adhering to the top side of the substrate 10.

Then, the dielectric layer 104, which is e.g., an oxide such as SiO₂, Al₂O₃ and TiO₂ or a nitride such as Si₃N₄ and AlN, is deposited (stacked). The deposition of the dielectric layer 104 may be done by a plasma CVD method, a reactive sputtering method, or the like.

A photoresist pattern (resist pattern) is formed using any known photolithography technique. The resist pattern includes openings at positions where the sensitive portion 30 and the yokes 40 (yokes 40a, 40b) are to be formed.

Subsequently, the soft magnetic material layer 105 of the Co alloy constituting the sensitive element 31 is deposited (stacked). The soft magnetic material layer 105 can be deposited using a sputtering method, for example.

Then, the resist pattern is removed, and also the soft magnetic material layer 105 on the resist pattern is removed (lifted off). As a result, the sensitive portion 30 and the yokes 40 (yokes 40a, 40b) composed of the soft magnetic material layer 105 are formed. In other words, the sensitive portion 30 and the yokes 40 are formed by a single deposition of the soft magnetic material layer 105.

Thereafter, the soft magnetic material layer 105 is provided with uniaxial magnetic anisotropy in the width direction (transverse direction) of the sensitive elements 31 of the sensitive portion 30 (see FIG. 1A). This impartation of the uniaxial magnetic anisotropy to the soft magnetic material layer 105 can be done by, for example, heat treatment at 400° C. in a rotating magnetic field of 3 kG (0.3 T) (heat treatment in a rotating magnetic field) and subsequent heat treatment at 400° C. in a static magnetic field of 3 kG (0.3 T) (heat treatment in a static magnetic field). At this time, similar uniaxial magnetic anisotropy is imparted to the soft magnetic material layer 105 constituting the yokes 40. However, the yokes 40 may not be provided with the uniaxial magnetic anisotropy because the yokes 40 are only required to serve as a magnetic circuit.

Then, the hard magnetic material layer 103 constituting the thin-film magnet 20 is magnetized. This magnetization of the hard magnetic material layer 103 can be done by applying a magnetic field larger than a coercive force of the hard magnetic material layer 103 in a static magnetic field or a pulsed magnetic field until the magnetization of the hard magnetic material layer 103 is saturated.

Subsequently, multiple magnetic sensors 1 formed on the substrate 10 are divided (cut) into individual magnetic sensors 1. In other words, the substrate 10, the adhesive layer 101, the control layer 102, the hard magnetic material layer 103, the dielectric layer 104, and the soft magnetic material layer 105 are cut such that each magnetic sensor 1 has a square planar shape as shown in the plan view of FIG. 1A. This results in the magnetic poles (north pole and south pole) of the thin-film magnet 20 being exposed on respective lateral sides of the divided (cut) hard magnetic material layer 103. Thus, the magnetized hard magnetic material layer 103 becomes the thin-film magnet 20. This division (cutting) can be done by a dicing method, a laser cutting method, or the like.

Note that an etching step of removing portions of the adhesive layer 101, the control layer 102, the hard magnetic material layer 103, the dielectric layer 104, and the soft magnetic material layer 105 between adjacent magnetic sensors 1 on the substrate 10 so as to shape these layers into a square planar shape (planar shape of the magnetic sensor 1 shown in FIG. 1) may take place before the step of dividing the multiple magnetic sensors 1 into individual magnetic sensors 1. Then, the exposed substrate 10 may be divided (cut).

Still alternatively, after the step of forming the laminate, the adhesive layer 101, the control layer 102, the hard magnetic material layer 103, and the dielectric layer 104 may be processed to have a square planar shape (planar shape of the magnetic sensor 1 shown in FIG. 1).

As compared to these methods, the manufacturing method described above involves simplified steps.

The magnetic sensor 1 is thus manufactured. Note that the impartation of the uniaxial magnetic anisotropy to the soft magnetic material layer 105 and/or the magnetization of the thin-film magnet 20 may be performed for each magnetic sensor 1 or multiple magnetic sensors 1 after the step of dividing the magnetic sensors 1 into individual magnetic sensors 1.

In the absence of the control layer 102, it would be necessary to heat the hard magnetic material layer 103 to 800° C. or more after the deposition thereof to bring about crystal growth and thereby impart the in-plane magnetic anisotropy. In contrast, providing the control layer 102, as in the magnetic sensor 1 of the present embodiment, eliminates the need for bringing about such crystal growth at a high temperature of 800° C. or more because the control layer 102 can facilitate the crystal growth.

The impartation of the uniaxial magnetic anisotropy to the sensitive elements 31 may be done by a magnetron sputtering method during the stacking of the soft magnetic material layer 105 of the Co alloy constituting the sensitive element 31, instead of the aforementioned heat treatment in the rotating magnetic field and heat treatment in the static magnetic field. The magnetron sputtering method forms a magnetic field using magnets and confines electrons generated by discharge to a surface of a target. The method thus increases the probability of collisions between the electrons and a gas to facilitate ionization of the gas, thereby increasing the film deposition rate. The magnetic field formed by the magnets used in the magnetron sputtering method imparts the uniaxial magnetic anisotropy to the soft magnetic material layer 105 concurrently with the deposition thereof. As such, the magnetron sputtering method allows omission of the step of imparting the uniaxial magnetic anisotropy through the heat treatment in the rotating magnetic field and the heat treatment in the static magnetic field.

### Characteristics of the Magnetic Sensor 1

Characteristics of the magnetic sensor 1 of the present embodiment are now described.

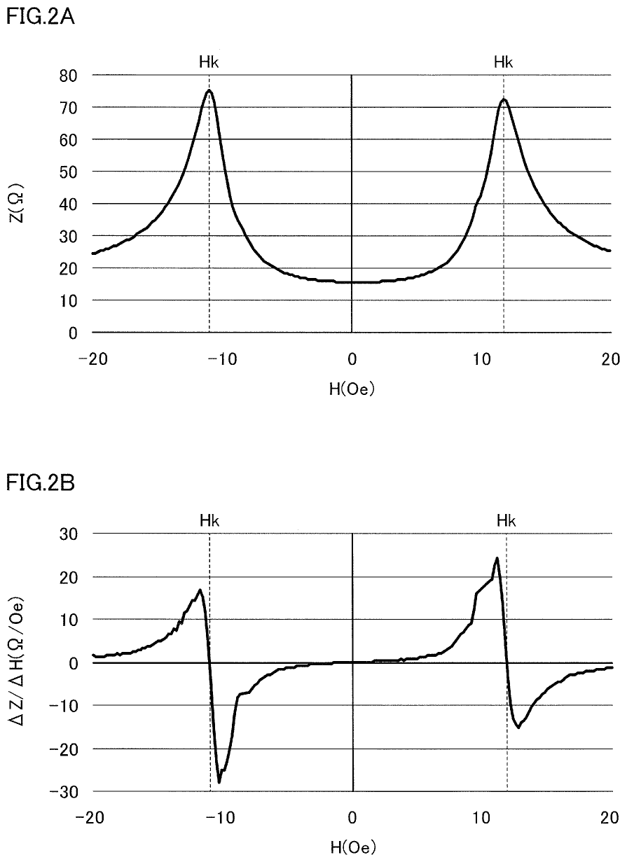

FIG. 2A illustrates relationship between an external magnetic field H (Oe) applied in the longitudinal direction of the sensitive element 31 of the magnetic sensor 1 and an impedance Z (Ω) generated in the sensitive element 31. FIG. 2B illustrates relationship between the external magnetic field H (Oe) applied in the longitudinal direction of the sensitive element 31 of the magnetic sensor 1 and changes in impedance Z of the sensitive element 31 relative to changes in the magnetic field H (ΔZ/ΔH (Ω/Oe)). Note that FIGS. 2A and 2B show results for both of the positive and negative directions of the magnetic field H. Also note that FIGS. 2A and 2B show results obtained by applying a 50 MHz high-frequency current to the sensitive element 31 of the magnetic sensor 1.

As shown in FIG. 2A, the sensitive element 31 in the magnetic sensor 1 of the present embodiment has its impedance changed according to the magnitude of the external magnetic field H applied to the sensitive element 31. More specifically, in this example, the impedance Z increases with an increase in the magnetic field H within the range from −12 (Oe) through 0 (Oe) to +12 (Oe). For example, the impedance Z decreases with an increase in the magnetic field H within the range exceeding 12 (Oe) (i.e., greater than +12 (Oe) or less than −12 (Oe)). Here, the magnetic field H at which the impedance Z takes a maximum value may be denoted as an anisotropic magnetic field Hk.

The anisotropic magnetic field Hk refers to the magnitude of the magnetic field at which the magnetic field reaches saturation in the magnetization curve in the direction of a hard axis of magnetization in a soft magnetic material that has an easy axis of magnetization and the hard axis of magnetization due to its uniaxial magnetic anisotropy. In other words, the anisotropic magnetic field Hk is defined as the strength of magnetic field that causes spins to be aligned in a certain direction; the anisotropic magnetic field Hk expresses, as a magnetic field, energy for causing spins to be aligned in a particular direction in the soft magnetic material.

FIG. 2B corresponds to the results of differentiating the data shown in FIG. 2A, i.e., the plot of the slope of the graph shown in FIG. 2A. Thus, in FIG. 2B, the value (slope) of ΔZ/ΔH at the magnetic field H=the anisotropic magnetic field Hk is 0.

### Selection of Magnetic Bias

In the magnetic sensor 1 of the present embodiment, the magnetic field H with a large slope in the magnetic field-impedance characteristics shown in FIG. 2A is always applied to the sensitive element 31 using the thin-film magnet 20 in order to improve detection sensitivity for a region where the strength of the magnetic field to be detected is near 0 (Oe). In other words, using the thin-film magnet 20, which is a permanent magnet, a unidirectional magnetic bias (direct current (DC) magnetic bias) is applied to each sensitive element 31 constituting the sensitive portion 30. In the present embodiment, the thin-film magnet 20 is configured to apply the magnetic bias along the longitudinal direction to each sensitive element 31 having uniaxial magnetic anisotropy in the transverse direction.

Now a description is given of the magnitude of the magnetic bias supplied by the thin-film magnet 20 to each sensitive element 31 of the sensitive portion 30 in the magnetic sensor 1 of the present embodiment.

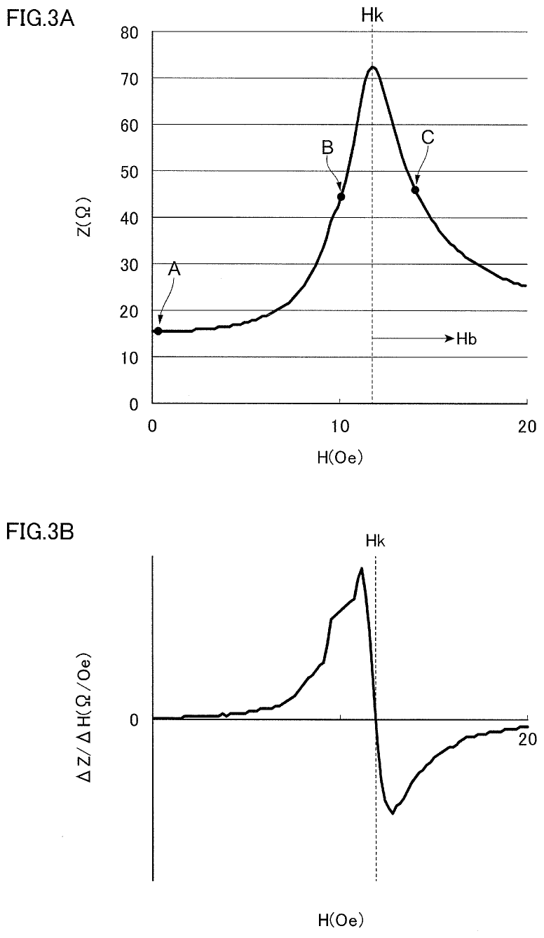

FIGS. 3A and 3B illustrate the magnitude of the magnetic bias Hb applied to the sensitive element 31 of the magnetic sensor 1 of the present embodiment. FIG. 3A is an enlargement of a portion of FIG. 2A where the magnetic field H assumes positive values, and FIG. 3B is an enlargement of a portion of FIG. 2B where the magnetic field H assumes positive values. Accordingly, in FIG. 3A, the horizontal axis represents the magnetic field H (Oe) and the vertical axis represents the impedance Z (Ω), and in FIG. 3B, the horizontal axis represents the magnetic field H (Oe) and the vertical axis represents the slope ΔZ/ΔH (Ω/Oe).

For a conventional magnetic sensor 1, the magnitude of the magnetic bias Hb has been determined based on a region where the amount of change ΔZ in the impedance Z relative to the amount of change ΔH in the applied magnetic field H is steepest in FIG. 3A (i.e., a region where the slope ΔZ/ΔH is largest in FIG. 3B). Thus, in the case of the sensitive element 31 having the characteristics as shown in FIGS. 2A to 3B, the conventional magnetic sensor 1 has been designed such that the magnetic bias Hb is selected from a region smaller than the anisotropic magnetic field Hk (e.g., see point B shown in FIG. 3A).

In contrast, the magnetic sensor 1 of the present embodiment is designed such that the magnetic bias Hb applied by the thin-film magnet 20 to the sensitive element 31 is selected from a region larger than the anisotropic magnetic field Hk (Hk<Hb). Note that an appropriate magnitude of the magnetic bias Hb varies for each magnetic sensor 1 depending on factors such as respective materials for the sensitive elements 31, the thin-film magnet 20, and the yokes 40, the shapes of these materials, their mutual positional relationship, and the magnitude and frequency of electric currents applied to the sensitive elements 31. As such, these relationships are only determined based on relative relationships, not based on absolute values.

### Reasons for Selection of DC Magnetic Bias

Now a description is given of reasons for selecting the magnetic bias Hb from the region larger than the anisotropic magnetic field Hk (Hk<Hb).

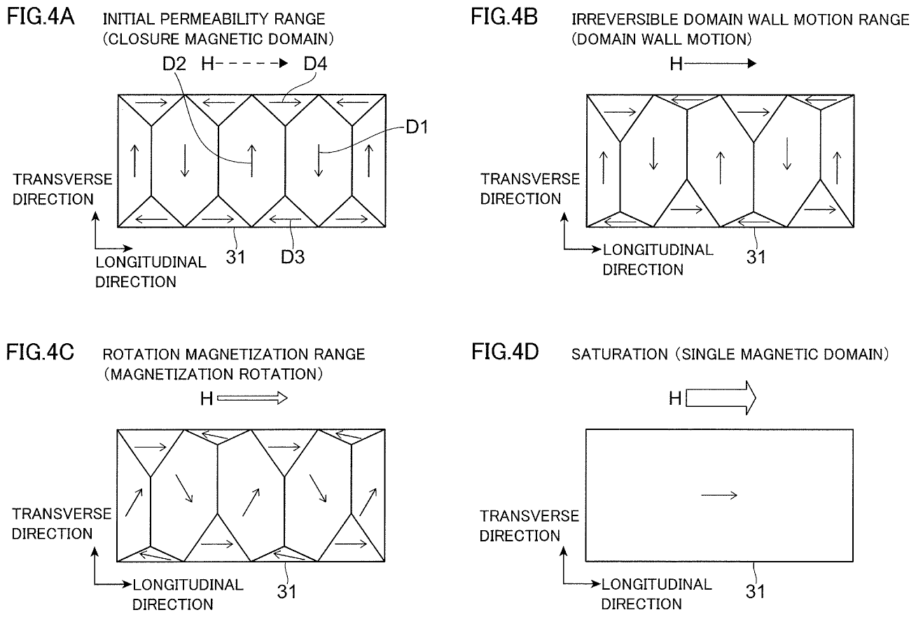

FIGS. 4A to 4D illustrate relationship between the strength of the magnetic field H applied to the sensitive element 31 of the magnetic sensor 1 of the present embodiment and changes in magnetic domains in the sensitive element 31. Here, it is assumed that uniaxial magnetic anisotropy is already imparted to the sensitive element 31 in the transverse direction thereof in an initial state where the magnetic field H is 0.

FIG. 4A illustrates an example magnetic domain structure of the sensitive element 31 in the state where the magnetic field H is very weak and near 0 (referred to as an “initial permeability range,” which is detailed below). FIG. 4B illustrates an example magnetic domain structure of the sensitive element 31 in the state where the magnetic field H is stronger than the state shown in FIG. 4A (referred to as an “irreversible domain wall motion range,” which is detailed below). FIG. 4C illustrates an example magnetic domain structure of the sensitive element 31 in the state where the magnetic field H is stronger than the state shown in FIG. 4B (referred to as a “rotation magnetization range,” which is detailed below). FIG. 4D illustrates an example magnetic domain structure of the sensitive element 31 in the state where the magnetic field H is stronger than the state shown in FIG. 4C (referred to as “saturation,” which is detailed below).

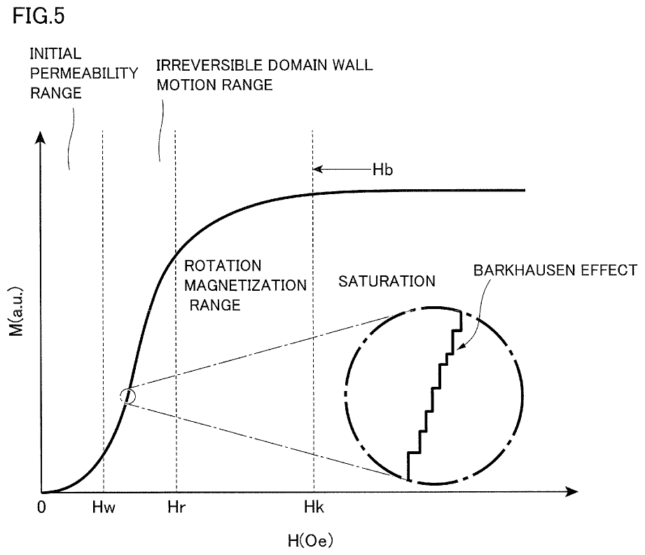

FIG. 5 illustrates relationship between the strength of the magnetic field applied to the sensitive element 31 of the magnetic sensor 1 of the present embodiment and the magnetization strength in the sensitive element 31. In FIG. 5, the horizontal axis represents the magnetic field H (Oe), and the vertical axis represents the magnetization M (a.u.). FIG. 5 also shows relationship of these magnetic field H and magnetization M with respect to the initial permeability range, the irreversible magnetic domain wall motion range, the rotation magnetization range, and the saturation described above.

The external magnetic field H applied to the sensitive element 31 ranging from 0 to a domain wall motion magnetic field Hw (details given below) is referred to as the “initial permeability range.”

In the initial permeability range, plural magnetic domains with different orientations of the magnetization M are formed in the sensitive element 31. More specifically, the sensitive element 31 includes: a first magnetic domain D1 and a second magnetic domain D2 with the magnetization M oriented in the direction of the easy axis of magnetization (transverse direction); and a third magnetic domain D3 and a fourth magnetic domain D4 with the magnetization M oriented in the direction of the hard axis of magnetization (longitudinal direction). The first magnetic domain D1 and the second magnetic domain D2 are opposite each other, and the third magnetic domain D3 and the fourth magnetic domain D4 are also opposite each other. These four magnetic domains are arranged in a clockwise direction in the figure, circularly from the first magnetic domain D1 to the third magnetic domain D3 to the second magnetic domain D2 to the fourth magnetic domain D4 to the first magnetic domain D1. As a result, these four magnetic domains collectively form a closure magnetic domain with a circular orientation of the magnetization M.

Macroscopically, the sensitive element 31 includes plural closure magnetic domains arranged in the longitudinal direction. In each closure magnetic domain, each area of the first magnetic domain D1 and the second magnetic domain D2 extending along the easy axis of magnetization is larger than each area of the third magnetic domain D3 and the fourth magnetic domain D4 extending along the hard axis of magnetization, based on the above relationship between the easy axis of magnetization and the hard axis of magnetization.

In the initial permeability range, the magnetic domains constituting each closure magnetic domain remain constant relative to changes in the magnetic field H. In other words, when the magnetic field H is in the range from 0 to the domain wall motion magnetic field Hw, the magnetic domain structure shown in FIG. 4A remains unchanged even with an increase in the magnetic field H.

The external magnetic field H applied to the sensitive element 31 ranging from the domain wall motion magnetic field Hw to a magnetization rotation magnetic field Hr (details given below) is referred to as the “irreversible domain wall motion range.”

Once the magnetic field H exceeds the domain wall motion magnetic field Hw, which is determined based on characteristics (such as material, structure, and dimensions) of the soft magnetic material layer 105 constituting the sensitive element 31, domain wall motion occurs in each closure magnetic domain, whereby positions of domain walls between respective adjacent magnetic domains move due to the effect of the magnetic field H. During this motion, in each closure magnetic domain, domain walls between the forth magnetic domain D4 with the same orientation of the magnetization M as the magnetic field H and the first and second magnetic domains D1, D2 adjacent to the fourth magnetic domain D4 move such that the area of the fourth magnetic domain D4 increases. Also, domain walls between the third magnetic domain D3 with an opposite orientation of the magnetization M from the magnetic field H and the first and second magnetic domains D1, D2 adjacent to the third magnetic domain D3 move such that the area of the third magnetic domain D3 decreases. As a result, the area of the fourth magnetic domain D4 increases as compared to that in the initial permeability range shown in FIG. 4A, and the areas of the remaining first to third magnetic domains D1-D3 decrease as compared to those in the initial permeability range.

The motion of the domain walls in the irreversible domain wall motion range occurs discontinuously along with an increase in the magnetic field H. As a result, the magnetization M of the sensitive element 31 as a whole relative to the magnetic field H changes stepwise (in a jagged fashion), rather than in a linear or curved fashion, as indicated by an enlarged portion in FIG. 5. This relationship between the magnetic field H and the magnetization M is called Barkhausen effect.

In the irreversible domain wall motion range, area ratios of the magnetic domains constituting each closure magnetic domain continue to gradually change relative to changes in the magnetic field H. More specifically, when the magnetic field H is in the range from the domain wall motion magnetic field Hw to the magnetization rotation magnetic field Hr, the area of the fourth magnetic domain D4 gradually increases while the areas of the first to third magnetic domains D1-D3 gradually decrease along with an increase in the magnetic field H.

The external magnetic field H ranging from the magnetization rotation magnetic field Hr to the anisotropic magnetic field Hk is referred to as the “rotation magnetization range.”

Once the magnetic field H exceeds the magnetization rotation magnetic field Hr, which is determined based on characteristics (such as material, structure, and dimensions) of the soft magnetic material layer 105 constituting the sensitive element 31, magnetization rotation occurs in each closure magnetic domain, whereby the orientation of the magnetization M in each of the first to third magnetic domains D1-D3 that has been oriented different from the magnetic field H gradually rotates such that it is oriented in the same direction as the magnetic field H, while positions of the domain walls between adjacent magnetic domains are substantially fixed. During this rotation, the fourth magnetic domain D4 remains unchanged because its orientation of magnetization is already aligned with the orientation of the magnetic field H.

In the rotation magnetization range, while the areas of the magnetic domains constituting each closure magnetic domain have little changes relative to changes in the magnetic field H, the orientation of the magnetization M in the first to third magnetic domains D1-D3 continues to gradually change. More specifically, when the magnetic field H is in the range from the magnetization rotation magnetic field Hr to the anisotropic magnetic field Hk, the orientation of the magnetization M of the fourth magnetic domain D4 does not change along with an increase in the magnetic field H but the orientation of the magnetization M of the remaining first to third magnetic domains D1-D3 gradually rotates such that it is aligned with the orientation of the magnetic field H.

However, in the rotation magnetization range, the orientation of the magnetization M of the first to third magnetic domains D1-D3 rotates continuously. Thus, in the rotation magnetization range, the changes in the magnetization M of the sensitive element 31 as a whole relative to the magnetic field H exhibit a curved form as shown in FIG. 5. In the rotation magnetization range, the rate of increase in the magnetization M of the sensitive element 31 as a whole relative to the increase in the magnetic field H slows down as the magnetic field H increases, and becomes substantially flat near the anisotropic magnetic field Hk, where the magnetization M takes a maximum value.

The region where the externally applied magnetic field H exceeds the anisotropic magnetic field Hk is referred to as the “saturation.”

Once the magnetic field H exceeds the above anisotropic magnetic field Hk, the orientation of the magnetization M in each closure magnetic domain is aligned with the orientation of the magnetic field H, i.e., the orientation of the magnetization M in the fourth magnetic domain D4. As a result, domain walls that have been present between adjacent magnetic domains disappear, resulting in the sensitive element 31 having only one (single) magnetic domain.

Upon saturation, the magnetization M of the sensitive element 31 as a whole will no longer change relative to the changes in the magnetic field H and will take a substantially constant value due to the change in the magnetic domain structure from having plural closure magnetic domains to having a single magnetic domain.

The state of the magnetic domains in the actual sensitive element 31 is now described.

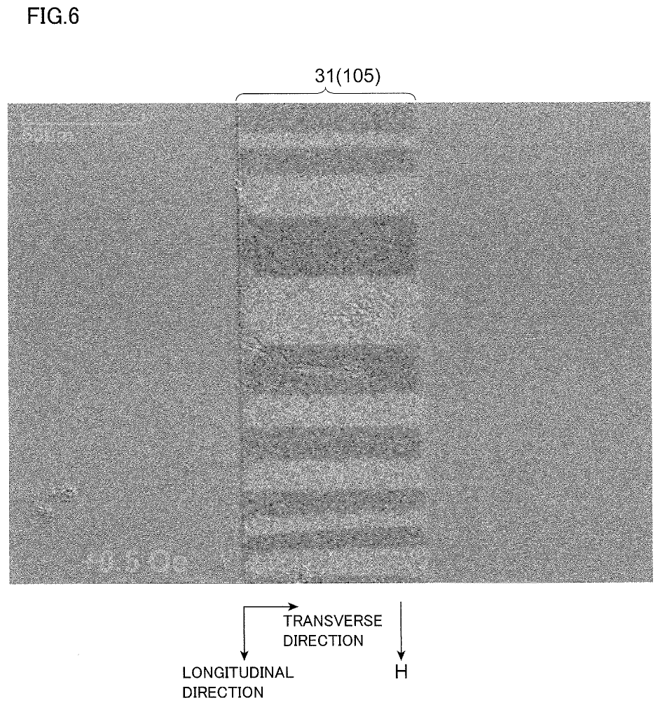

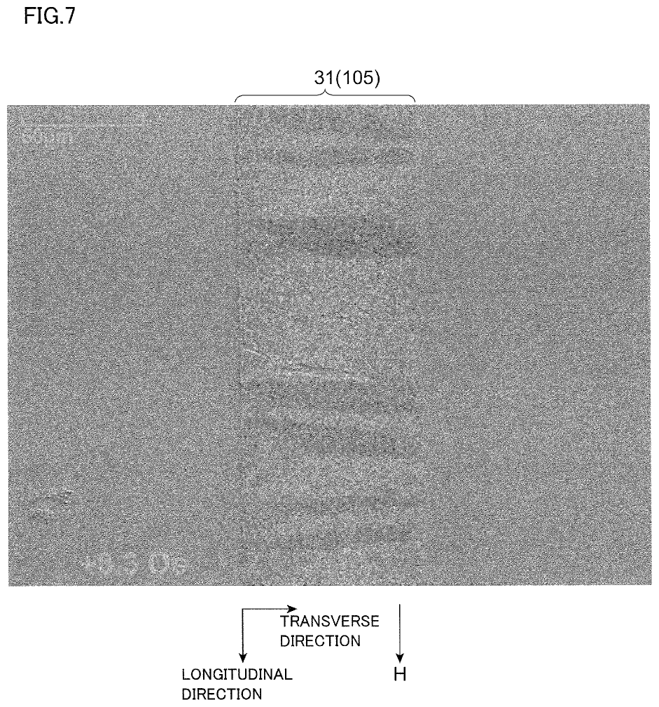

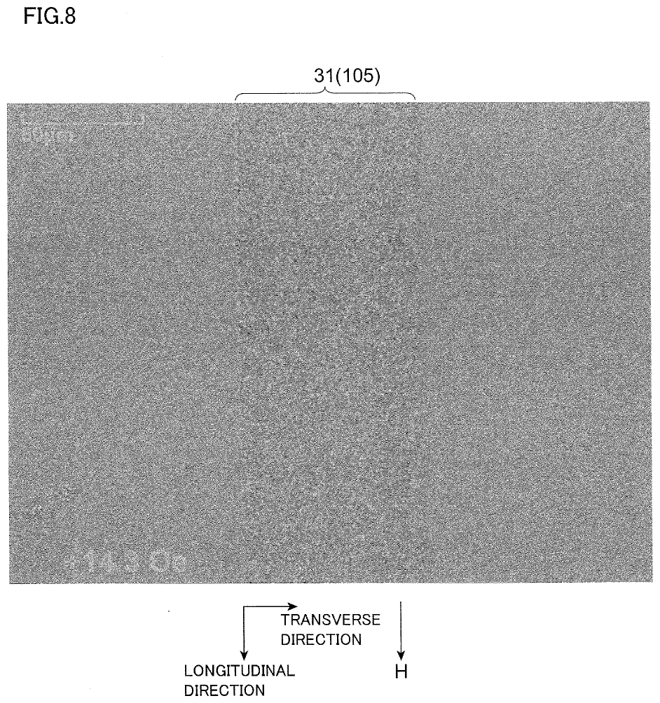

FIGS. 6-8 are photographs capturing the state of the magnetic domains when the DC magnetic bias Hb with different magnitudes was applied to the sensitive element 31 of the magnetic sensor 1. FIG. 6 shows the state of the magnetic domain when the DC magnetic bias Hb with a magnitude A (+0.5 Oe) was applied to the sensitive element 31. FIG. 7 shows the state of the magnetic domain when the DC magnetic bias Hb with a magnitude B (+8.3 Oe) was applied to the sensitive element 31. FIG. 8 shows the state of the magnetic domain when the DC magnetic bias Hb with a magnitude C (+14.3 Oe) was applied to the sensitive element 31. The photographs of FIGS. 6-8 were taken by Neomagnesia Lite from Neoark Corporation. FIG. 3A described above also shows these magnitudes A-C.

From FIG. 6, it can be seen that plural magnetic domains each extending along the transverse direction of the sensitive element 31 (corresponding to the first and second magnetic domains D1, D2) are arranged in the longitudinal direction. Though difficult to discern, it can also be seen from FIG. 6 that plural magnetic domains each extending along the longitudinal direction of the sensitive element 31 (corresponding to the third and fourth magnetic domains D3, D4) are arranged in the longitudinal direction at both transversal ends of the sensitive element 31. In this example, the magnitude A (+0.5 Oe) of the DC magnetic bias Hb is included in the initial permeability range shown in FIG. 5. Thus, the magnetic domain structure of the sensitive element 31 shown in FIG. 6 is considered to be in the state shown in FIG. 4A.

From FIG. 7, it can be seen that plural magnetic domains present at one transversal end (left end in FIG. 7) of the sensitive element 31 (corresponding to the fourth magnetic domain D4) are larger than what is shown in FIG. 6. Meanwhile, it can be seen from FIG. 7 that plural magnetic domains extending along the transverse direction of the sensitive element 31 (corresponding to the first and second magnetic domains D1, D2) and plural magnetic domains present at the other transversal end (right end in FIG. 7) of the sensitive element 31 (corresponding to the third magnetic domain D3) are smaller than what is shown in FIG. 6. In this example, the magnitude B (+8.3 Oe) of the DC magnetic bias Hb is included in the irreversible domain wall motion range or the rotation magnetization range shown in FIG. 5. Thus, the magnetic domain structure of the sensitive element 31 shown in FIG. 7 is considered to be in the state shown in FIG. 4B or 4C.

From FIG. 8, it can be seen that the sensitive element 31 as a whole constitutes one magnetic domain (single magnetic domain) as the entire sensitive element 31 has a substantially uniform concentration. In this example, the magnitude C (+14.3 Oe) of the DC magnetic bias Hb is included in the saturation shown in FIG. 5. Thus, the magnetic domain structure of the sensitive element 31 shown in FIG. 8 is considered to be in the state shown in FIG. 4D.

In the present embodiment, the magnitude of the magnetic field H applied to each sensitive element 31 using the thin-film magnet 20, i.e., the magnitude of the DC magnetic bias Hb has a larger value than the anisotropic magnetic field Hk of the sensitive element 31. In other words, in the present embodiment, the magnitude of the above magnetic bias Hb is selected to be the magnitude of a saturation magnetic field at which the magnetic field-magnetization characteristics saturate in the soft magnetic material layer 105 constituting the sensitive element 31. In still other words, in the present embodiment, the impedance Z is measured (any change in the externally applied magnetic field H is measured) in the state where the sensitive element 31 is having the single magnetic domain structure shown in FIGS. 4A and 8 due to the application of the DC magnetic bias Hb.

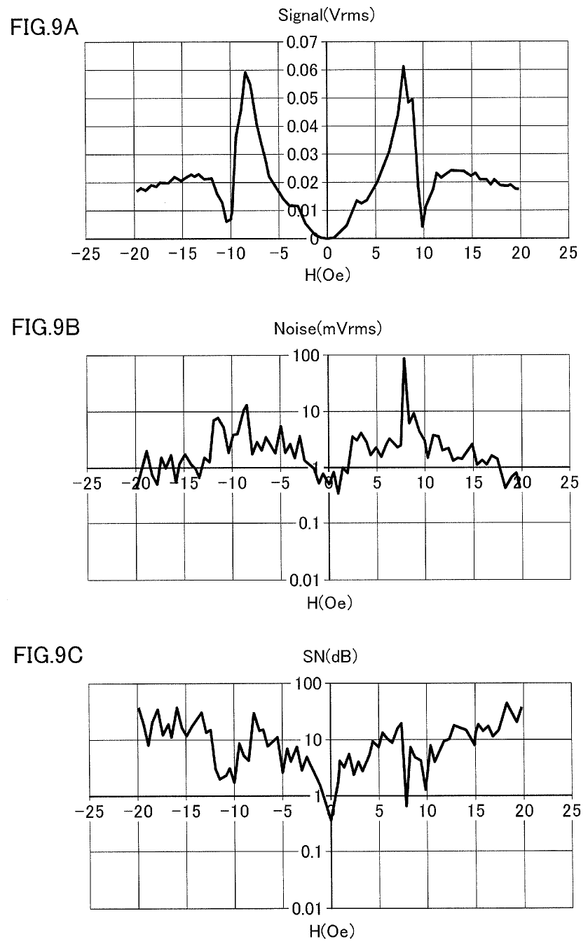

FIGS. 9A to 9C illustrate relationship between signals and noise output from the magnetic sensor 1 of the present embodiment and the SN ratio. FIG. 9A shows a graph associated with signals, where the horizontal axis represents the strength of the external magnetic field H (Oe) applied to the magnetic sensor 1, and the vertical axis represents voltage (Vrms) corresponding to the signal output. FIG. 9B shows a graph associated with noise, where the horizontal axis represents the strength of the external magnetic field H (Oe) applied to the magnetic sensor 1, and the vertical axis represents voltage (mVrms) corresponding to the noise output. FIG. 9C shows a graph associated with the SN ratio obtained based on the magnetic field-signal characteristics shown in FIG. 9A and the magnetic field-noise characteristics shown in FIG. 9B, where the horizontal axis represents the strength of the external magnetic field H (Oe) applied to the magnetic sensor 1, and the vertical axis represents the SN ratio (dB). Note that the vertical axis in FIG. 9C is a log scale. The data used in the graphs shown in FIGS. 9A-9C are obtained by applying pulsed voltages to the magnetic sensor 1 and measuring changes in voltage output from the magnetic sensor 1. In this example, calibration has been performed such that the signal voltage is 0 when the magnetic field H is 0.

The signal voltage is proportional to ΔZ/ΔH, which is a ratio between the amount of change ΔH in the magnetic field H and the amount of change ΔZ in the impedance Z. That is, the graph of FIG. 9A can be viewed as corresponding to FIG. 3B described above. In this example, it can be seen that a maximum value of the signal voltage shown in FIG. 9A lies near ±8 (Oe) or, in other words, the slope of ΔZ/ΔH is maximum at about ±8 (Oe). In this example, it can also be seen that a minimum value of the signal voltage shown in FIG. 9A lies near ±10 (Oe) or, in other words, the slope of ΔZ/ΔH is minimum at about ±10 (Oe). These results suggest that the anisotropic magnetic field Hk of the sensitive element 31 lies near ±10 (Oe) in the magnetic sensor 1 used in this experiment.

Comparing the SN ratios between when, for example, the magnetic field H assumes values from −10 (Oe) to +10 (Oe) and when the magnetic field H assumes negative values below −10 (Oe) or positive values above +10 (Oe) in FIG. 9C, it can be seen that the latter case has smaller variations in the SN ratio than the former case. From this result, it can be understood that making the DC magnetic bias Hb, as applied by the thin-film magnet 20 to the sensitive element 31 in the magnetic sensor 1, greater than the anisotropic magnetic field Hk of the soft magnetic material layer 105 constituting the sensitive element 31 can reduce a decrease in the SN ratio at the obtained output.

### Other Notes

While the foregoing description uses an example the anisotropic magnetic field Hk assumes positive values, the present invention is of course applicable to cases where the anisotropic magnetic field Hk assumes negative values. In such cases, the magnetic sensor 1 may be designed such that the DC bias Hb applied by the thin-film magnet 20 to the sensitive element 31 is selected from the range below the anisotropic magnetic field Hk (Hb<Hk).

While, in the present embodiment, the DC magnetic bias Hb is applied to the sensitive element 31 using a thin-film magnet 20 made of a permanent magnet, the present invention is not limited to this embodiment. For example, the DC magnetic bias Hb may be applied to the sensitive element 31 using an electromagnet or the like.

While the foregoing description of the present embodiment uses an example where the thin-film magnet 20, the sensitive portion 30 (sensitive elements 31) and the like are integrally laminated on the substrate 10 to form the magnetic sensor 1, the present invention is not limited to this embodiment. For example, a configuration may be adopted in which a magnet portion composed of the thin-film magnet 20 or the like and the sensitive element 31 are separate from each other.

While the foregoing description of the present embodiment uses an example where the magnetic sensor 1 includes the sensitive elements 31 of a thin-film shape, the present invention is not limited to this embodiment. For example, the present invention is applicable to a magnetic sensor 1 including linear sensitive elements 31.

### REFERENCE SIGNS LIST

1 Magnetic sensor
10 Substrate
20 Thin-film magnet
30 Sensitive portion
31 Sensitive element
32 Connecting portion
33 Terminal portion
40 (40a, 40b) Yoke
101 Adhesive layer
102 Control layer
103 Hard magnetic material layer
104 Dielectric layer
105 Soft magnetic material layer

1-4. (canceled)

5. A magnetic sensor comprising:
a sensitive layer made of a soft magnetic material with uniaxial magnetic anisotropy, the sensitive layer being configured to sense a magnetic field by a magnetic impedance effect; and
a magnet layer made of a magnetized hard magnetic material and disposed to face the sensitive layer, the magnet layer being configured to apply a DC magnetic bias in a direction intersecting a direction of the uniaxial magnetic anisotropy in the sensitive layer, the DC magnetic bias having a greater value than an anisotropic magnetic field of the sensitive layer.

6. The magnetic sensor according to claim 5, wherein the magnet layer is configured to apply, as the DC magnetic bias, a magnetic field with a largest slope in a magnetic field-impedance curve within a range of values greater than the anisotropic magnetic field of the sensitive layer, the magnetic field-impedance curve associating magnetic fields applied to the sensitive layer with changes in impedance of the sensitive layer.

7. The magnetic sensor according to claim 5, further comprising a guiding layer configured to guide magnetic lines of force passing through the magnet layer to the sensitive layer.

8. The magnetic sensor according to claim 6, further comprising a guiding layer configured to guide magnetic lines of force passing through the magnet layer to the sensitive layer.

9. A magnetic sensor comprising:
a sensitive element made of a soft magnetic material, the sensitive element having a longitudinal direction and a transverse direction, the sensitive element having uniaxial magnetic anisotropy in a direction intersecting the longitudinal direction, the sensitive element being configured to sense a magnetic field by a magnetic impedance effect; and
an applicator configured to apply a DC magnetic bias in the longitudinal direction of the sensitive element, the DC magnetic bias corresponding to a saturation magnetic field of the sensitive element.
